(19) United States
(12) Patent Application Publication
(10) Pub. No.: US 2011/0146772 A1
(43) Pub. Date: Jun. 23, 2011

(54) METHOD FOR MANUFACTURING QUANTUM DOT-SENSITIZED SOLAR CELL ELECTRODE, QUANTUM DOT-SENSITIZED SOLAR CELL ELECTRODE AND QUANTUM DOT-SENSITIZED SOLAR CELL

(75) Inventor: Hiroaki TADA, Nara-shi (JP)

(73) Assignees: NIPPON SHOKUBAI CO., LTD., Osaka (JP); KINKI UNIVERSITY, Osaka (JP)

(21) Appl. No.: 12/888,186

(22) Filed: Sep. 22, 2010

(30) Foreign Application Priority Data
Sep. 25, 2009 (JP) 2009-220404

(51) Int. Cl. H01L 31/0248; H01L 31/18; B82Y 30/00; B82Y 40/00

(52) U.S. Cl. 136/255; 438/85; 977/774; 257/E31.015; 438/63

(57) ABSTRACT

Provided is a manufacturing method for a quantum dot-sensitized solar cell electrode for the production of a quantum dot-sensitized solar cell far more excellent in solar energy capture efficiency than ever before. Also provided is a quantum dot-sensitized solar cell electrode obtained by such manufacturing method. Also provided is a quantum dot-sensitized solar cell using such electrode. Also provided is a quantum dot-sensitized solar cell electrode for the production of a quantum dot-sensitized solar cell far more excellent in solar energy capture efficiency than ever before. Also provided is a quantum dot-sensitized solar cell using such electrode. The manufacturing method of the present invention is a manufacturing method for a quantum dot-sensitized solar cell electrode including quantum dots being semiconductor nanoparticles and having loaded on a porous n-type semiconductor electrode, the method including subjecting the porous n-type semiconductor electrode to photoirradiation while the electrode being immersed in a metal ion-containing solution.

### TECHNICAL FIELD

The present invention relates to a manufacturing method for a quantum dot-sensitized solar cell electrode, a quantum dot-sensitized solar cell electrode, and a quantum dot-sensitized solar cell.

### BACKGROUND ART

A dye-sensitized solar cell is inexpensive and has relatively high photoelectric conversion efficiency. Therefore, the dye-sensitized solar cell have attracted a great deal of attention as a sustainable energy source for the next generation (Japanese Patent Application Laid-open No. 2005-19130).

However, the dye-sensitized solar cell has a drawback in that higher photoelectric conversion efficiency is hard to be achieved because an organic dye sensitizer is liable to be degraded, and in particular, is insufficient in lifetime and durability in the presence of oxygen, and further, the absorption wavelength region is generally limited to an ultraviolet to visible light region.

There are recent reports on a quantum dot-sensitized solar cell including quantum dots being semiconductor nanoparticles and having loaded on a semiconductor electrode (Japanese Patent Application Laid-open No. 2008-16369 and Japanese Patent Application Laid-open No. 2008-287900). The quantum dots are satisfactory in durability as compared to the organic dye sensitizer, and are semiconductor particles each having a size of nanometer order. Hence, there are advantages in that solar energy capture efficiency is improved by an effect based on multiple exciton generation (MEG) and that an absorption wavelength can be controlled by controlling the size of each of particles. In particular, it is important that the quantum dots are semiconductor particles each having a size of nanometer order, and hence the solar energy capture efficiency is improved by the effect based on multiple exciton generation (MEG). For example, the solar energy capture efficiency in the case of using the quantum dots, which are semiconductor nanoparticles, is far more excellent than that in the case where a chalcogenide semiconductor does not exist as nanoparticles but exist as a film on a semiconductor electrode (Japanese Patent Application Laid-open No. 2009-70768).

The following methods are known as methods of loading quantum dots on a semiconductor electrode: (1) a method involving preliminarily producing quantum dots and then loading the quantum dots on an electrode using coupling molecules such as mercaptoacetic acid (J. Am. Chem. Soc., 128, 2385., J. Phys. Chem. B, 2006, 110, 9556.); (2) a method involving depositing quantum dots in a chemical bath (J. Phys. Chem., 98, 5338., J. Photochem. Photobiol. A, 181, 306, 2006., Appl. Phys. Lett., 91, 23116, 2007.); and (3) a method involving depositing quantum dots by an successive ionic layer adsorption (SILAR) method (Appl. Surf. Sci., 22/3, 1061, 1985., J. Electrochem. Soc., 137, 2915, 1990.).

However, in the method according to the above-mentioned item (1), there is a problem in that the presence of an organic matter between the quantum dots and the electrode degrades electron transfer efficiency. Further, in the methods according to the above-mentioned items (2) and (3), there are problems in that the reproducibility is poor and that the level of solar energy capture efficiency is not enough to be used in practical applications.

### SUMMARRY OF INVENTION

### Technical Problem

An object of the present invention is to provide a manufacturing method for a quantum dot-sensitized solar cell electrode for the production of a quantum dot-sensitized solar cell far more excellent in solar energy capture efficiency, which is evaluated with IPCE, power conversion efficiency, and the like, than ever before. Another object of the present invention is to provide a quantum dot-sensitized solar cell electrode obtained by such manufacturing method. Still another object of the present invention is to provide a quantum dot-sensitized solar cell using such electrode and being far more excellent in solar energy capture efficiency, which is evaluated with IPCE, power conversion efficiency, and the like, than ever before.

Another object of the present invention is to provide a quantum dot-sensitized solar cell electrode for the production of a quantum dot-sensitized solar cell far more excellent in solar energy capture efficiency, which is evaluated with IPCE, power conversion efficiency, and the like, than ever before. Another object of the present invention is to provide a quantum dot-sensitized solar cell using such electrode and being far more excellent in solar energy capture efficiency, which is evaluated with IPCE, power conversion efficiency, and the like, than ever before.

### Solution to Problem

A manufacturing method of the present invention is a manufacturing method for a quantum dot-sensitized solar cell electrode including quantum dots, which being semiconductor nanoparticles and having loaded on a porous n-type semiconductor electrode, the method including subjecting the porous n-type semiconductor electrode to photoirradiation while the electrode being immersed in a metal ion-containing solution.

In a preferred embodiment, the above-mentioned metal ion-containing solution includes a compound having a Group 16 element.

In a preferred embodiment, the above-mentioned photoirradiation is UV light irradiation.

According to another aspect of the present invention, there is provided a quantum dot-sensitized solar cell electrode. The quantum dot-sensitized solar cell electrode of the present invention is obtained by the manufacturing method of the present invention.

According to another aspect of the present invention, there is provided a quantum dot-sensitized solar cell. The quantum dot-sensitized solar cell of the present invention includes the above-mentioned quantum dot-sensitized solar cell electrode.

In a preferred embodiment, the above-mentioned quantum dot-sensitized solar cell has IPCE efficiency of 70% or more.

According to another aspect of the present invention, there is provided a quantum dot-sensitized solar cell electrode. The quantum dot-sensitized solar cell electrode includes quantum dots being Group 16 element semiconductor nanoparticles and having loaded on a porous n-type semiconductor electrode, in which, when the Group 16 element semiconductor nanoparticles are represented by MKₓ (M represents a metal element, K represents a Group 16 element, and x represents the number of atoms of K with respect to the number of atoms of M defined as 1) and the expression a=x/y (y represents the valence of M) is established, the expression 0.3<a<0.6 is satisfied.

According to another aspect of the present invention, there is provided a quantum dot-sensitized solar cell. The quantum dot-sensitized solar cell of the present invention includes the above-mentioned quantum dot-sensitized solar cell electrode.

In a preferred embodiment, the above-mentioned quantum dot-sensitized solar cell has IPCE efficiency of 70% or more.

### Advantageous Effects of Invention

According to the present invention, there can be provided a manufacturing method for a quantum dot-sensitized solar cell electrode for the production of a quantum dot-sensitized solar cell far more excellent in solar energy capture efficiency, which is evaluated with IPCE, power conversion efficiency, and the like, than ever before. In addition, there can be provided a quantum dot-sensitized solar cell electrode obtained by such manufacturing method. Further, there can be provided a quantum dot-sensitized solar cell using such electrode and being far more excellent in solar energy capture efficiency, which is evaluated with IPCE, power conversion efficiency, and the like, than ever before.

Such effects as described above can be exerted by employing, as a method of loading quantum dots, which are semiconductor nanoparticles, on a porous n-type semiconductor electrode, a method involving subjecting the porous n-type semiconductor electrode to photoirradiation while the electrode being immersed in a metal ion-containing solution, during the manufacture of the quantum dot-sensitized solar cell electrode. The quantum dot-sensitized solar cell using the quantum dot-sensitized solar cell electrode obtained by the manufacturing method of the present invention can achieve IPCE efficiency of 70% or more. This is far more excellent than the IPCE efficiency of a conventional quantum dot-sensitized solar cell, which is around 60% even in a high-performance type. In addition, the quantum dot-sensitized solar cell using the quantum dot-sensitized solar cell electrode obtained by the manufacturing method of the present invention can exert such a high level of power conversion efficiency that may indicate its high practical applicability in the future.

According to the present invention, there can also be provided a quantum dot-sensitized solar cell electrode for the production of a quantum dot-sensitized solar cell far more excellent in solar energy capture efficiency, which is evaluated with IPCE, power conversion efficiency, and the like, than ever before. There can also be provided a quantum dot-sensitized solar cell using such electrode and being far more excellent in solar energy capture efficiency, which is evaluated with IPCE, power conversion efficiency, and the like, than ever before.

Such effects as described above can also be exertedby employing, as the quantum dot-sensitized solar cell electrode, a quantum dot-sensitized solar cell electrode including quantum dots being Group 16 element semiconductor nanoparticles and having loaded on a porous n-type semiconductor electrode so that, when the Group 16 element semiconductor nanoparticles are represented by MKₓ (M represents a metal element, K represents a Group 16 element, and x represents the number of atoms of K with respect to the number of atoms of M defined as 1) and the expression a=x/y (y represents the valence of M) is established, the value a falls within a given range of values.

### BRIEF DESCRIPTION OF DRAWINGS

FIG. 1 are graphs illustrating relationships between UV light irradiation time (tₚ) or adsorption time (tₐ) and a quantum dot formation amount in quantum dot-sensitized solar cell electrodes.

FIG. 2 are graphs illustrating relationships between UV light irradiation time (tₚ) and a quantum dot formation amount in quantum dot-sensitized solar cell electrodes (L-1) to (L-6) obtained in Example 2.

FIG. 3 are graphs plotting relationships between an IPCE amount and a quantum dot formation amount in a quantum dot-sensitized solar cell (SC-S-3) obtained in Example 3, a quantum dot-sensitized solar cell (SC-L-3) obtained in Example 4, and a quantum dot-sensitized solar cell (Comparative SC-L-1) obtained in Comparative Example 4.

### DESCRIPTION OF EMBODIMENTS

### <<Manufacturing Method for Quantum Dot-Sensitized Solar Cell Electrode>>

A manufacturing method of the present invention is a manufacturing method for a quantum dot-sensitized solar cell electrode including quantum dots being semiconductor nanoparticles and having loaded on a porous n-type semiconductor electrode, the method including subjecting the porous n-type semiconductor electrode to photoirradiation while the electrode being immersed in a metal ion-containing solution.

The porous n-type semiconductor electrode is, for example, an electrode having a layer (hereinafter sometimes referred to as a semiconductor layer) formed of any appropriate porous n-type semiconductor having a photocatalytic action.

Preferred examples of the above-mentioned semiconductor layer include layers of porous n-type semiconductors such as titanium oxide (TiO₂), zinc oxide (ZnO), and strontium titanate (SrTiO₃). Of those, a titanium oxide layer is more preferred. This is because the titanium oxide layer has an excellent photocatalytic action, and hence, metal ions in a metal ion-containing solution are reduced by the photocatalytic action induced by photoirradiation in the manufacturing method of the present invention, and are easily deposited as quantum dots, which are semiconductor nanoparticles.

Any appropriate transparent electrode may be employed as the above-mentioned electrode. Examples of the electrode include indium tin oxide (ITO), fluorine-doped tin oxide (FTO), and antimony-doped tin oxide (ATO).

The above-mentioned electrode maybe provided with a supporting substrate, as necessary. Any appropriate supporting substrate may be employed as the above-mentioned supporting substrate. Examples of the supporting substrate include a glass substrate and a plastic substrate.

The above-mentioned metal ion-containing solution contains such metal ions that are deposited or deposited and simultaneously oxidized by a compound having a Group 16 element present in the solution, and loaded as quantum dots, which are semiconductor nanoparticles, on the above-mentioned porous n-type semiconductor electrode. Examples of such metal ions include Cd ions, Pb ions, Mo ions, Ag ions, Bi ions, Cu ions, In ions, Ga ions, Ge ions, Si ions, Zn ions, and Fe ions. Of those, in the case of being used as a quantum dot, Cd ions are preferred because they are excellent in solar energy capture efficiency.

The above-mentioned metal ion-containing solution may contain a compound having a Group 16 element. Examples of the Group 16 element include O, S, Se, and Te. Any appropriate compound may be employed as the compound having a Group 16 element as long as the compound has an oxidation ability. The compound is, for example, S₈.

The above-mentioned metal ion-containing solution may contain any appropriate solvent. Examples of such solvent include alcohols such as methanol and ethanol.

The above-mentioned metal ion-containing solution may contain mercaptoacetic acid in order to adjust the particle size of each of quantum dots. When the above-mentioned metal ion-containing solution contains mercaptoacetic acid, the concentration of mercaptoacetic acid contained in the solution is preferably in the range of 1.72×10⁻⁶ mol/L to 1.72×10⁻³ mol/L as an initial concentration. When the concentration (initial concentration) of mercaptoacetic acid contained in the above-mentioned metal ion-containing solution is in the above-mentioned range, photoinduced electron transfer from quantum dots to a porous n-type semiconductor electrode is sufficiently promoted, and a decrease in photoabsorption amount attributed to a quantum size effect due to an excess reduction in particle size can also be suppressed.

In the above-mentioned photoirradiation method, one has only to apply light having any appropriate wavelength. It is preferred to apply light having such a wavelength that a porous n-type semiconductor electrode exhibits a photocatalytic action. It is typically preferred to apply UV light.

In the manufacturing method of the present invention, after the above-mentioned photoirradiation, as necessary, an electrode surface is washed with any appropriate washing solvent and dried.

According to the manufacturing method of the present invention, a porous n-type semiconductor electrode having a photocatalytic action is subjected to photoirradiation while being immersed in a metal ion-containing solution. Hence, a metal ion in the solution and a compound having a Group 16 element contained, as necessary, in the solution undergo reduction and oxidation efficiently by a photocatalytic action, and are deposited and loaded as quantum dots, which are semiconductor nanoparticles, on the electrode in a very efficient manner. To be specific, for example, when a Cd ion and S₈ are contained in the metal ion-containing solution, the Cd ion in the solution is reduced and deposited as Cd by a photocatalytic action induced by photoirradiation, is simultaneously oxidized by S₈ in the solution, and CdS is finally deposited as semiconductor nanoparticles on the electrode in a very efficient manner.

The quantum dot-sensitized solar cell electrode obtained by the manufacturing method of the present invention has quantum dots being semiconductor nanoparticles and having loaded on a porous n-type semiconductor electrode. Examples of such quantum dots, which are semiconductor nanoparticles, include chalcogenide semiconductor nanoparticles and Si nanoparticles. Examples of the chalcogenide semiconductor nanoparticles include: nanoparticles of metal sulfides such as CdS, MoS, FeS, In₂S₃, NaInS₂, ZnIn₂S₄, ZnₓCd₁₋ₓS, Cd₂In₂S₄, AgGaS₂, PbS, and Ag₂S; nanoparticles of metal selenides such as CdSe, PbSe, CuInSe₂, CuInGaSe₂, and CuInGaSe; and nanoparticles of metal tellurides such as CdTe. Of those, nanoparticles of metal sulfides are preferred and nanoparticles of cadmium sulfide are more preferred because the effects of the present invention can be additionally effectively exerted.

Any appropriate size may be employed as the particle size of each of the above-mentioned quantum dots, which are semiconductor nanoparticles, as long as the size is of nanometer order. For example, the particle size is preferably in the range of 1 nm to 20 nm, more preferably in the range of 1 nm to 10 nm. When the particle size of each of the above-mentioned quantum dots, which are semiconductor nanoparticles, falls within the above-mentioned range, solar energy capture efficiency can be improved effectively by an effect based on multiple exciton generation (MEG).

### <<Quantum Dot-Sensitized Solar Cell Electrode>>

The quantum dot-sensitized solar cell electrode of the present invention is a quantum dot-sensitized solar cell electrode including quantum dots being Group 16 element semiconductor nanoparticles and having loaded on a porous n-type semiconductor electrode, in which, when the Group 16 element semiconductor nanoparticles are represented by MKₓ (M represents a metal element, K represents a Group 16 element, and x represents the number of atoms of K with respect to the number of atoms of M defined as 1) and the expression a=x/y (y represents the valence of M) is established, the expression 0.3<a<0.6 is satisfied.

When the value a satisfies the expression 0.3<a<0.6 as described above, excellent solar energy capture efficiency, which was not able to be achieved by a conventional quantum dot-sensitized solar cell electrode, can be achieved. When the value a satisfies the expression 0.3<a<0.6 as described above, the value of the number of atoms of M and the value of the number of atoms of K become close to each other in the Group 16 element semiconductor nanoparticles MKₓ, which allows performance inherent in semiconductor nanoparticles to be exhibited sufficiently. Thus, a quantum dot-sensitized solar cell far more excellent in solar energy capture efficiency, which is evaluated with IPCE, power conversion efficiency, and the like, than ever before can be provided.

The quantum dot-sensitized solar cell electrode of the present invention can be manufactured by the above-mentioned manufacturing method of the present invention. In other words, when the quantum dot-sensitized solar cell electrode of the present invention is manufactured by the manufacturing method of the present invention, the quantum dot-sensitized solar cell electrode of the present invention has the above-mentioned quantum dots being semiconductor nanoparticles and having loaded on the above-mentioned porous n-type semiconductor electrode. Besides, the quantum dots are directly deposited on the porous n-type semiconductor electrode by subjecting the electrode to photoirradiation while the electrode being immersed in a metal ion-containing solution.

When the quantum dot-sensitized solar cell electrode of the present invention is manufactured by the manufacturing method of the present invention, the quantum dot-sensitized solar cell electrode of the present invention has the above-mentioned quantum dots, which have been formed by the above-mentioned characteristic manufacturing method, directly loaded on the above-mentioned porous n-type semiconductor electrode. Therefore, it becomes possible to achieve excellent solar energy capture efficiency, which is evaluated with IPCE, power conversion efficiency, and the like and was not able to be achieved by a quantum dot-sensitized solar cell formed of a conventional quantum dot-sensitized solar cell electrode, through, for example, the following actions: (1) quantum dots are directly formed on a porous n-type semiconductor electrode; (2) a metal ion in the above-mentioned solution and a compound having a Group 16 element contained, as necessary, in the solution efficiently undergo reduction and oxidation by a photocatalytic action, and are deposited and loaded as quantum dots, which are semiconductor nanoparticles, on the electrode in a very efficient manner; (3) a porous n-type semiconductor electrode having a photocatalytic action is subjected to photoirradiation while being immersed in a metal ion-containing solution to deposit quantum dots, and hence quantum dot-sensitized solar cell electrodes having the same quality are obtained with good reproducibility; and (4) the particle size of each of quantum dots can be properly controlled by controlling the wavelength of irradiation light in photoirradiation.

### <<Quantum Dot-Sensitized Solar Cell>>

The quantum dot-sensitized solar cell of the present invention includes the quantum dot-sensitized solar cell electrode of the present invention.

The quantum dot-sensitized solar cell of the present invention typically has a configuration including the quantum dot-sensitized solar cell electrode of the present invention and a counter electrode. The counter electrode may be provided with a supporting substrate, as necessary.

Any appropriate counter electrode may be employed as the above-mentioned counter electrode. Examples of the counter electrode include titanium, nickel, gold, silver, copper, carbon, a transparent electrode, and a conductive polymer. Examples of the transparent electrode include those as described above. Examples of the conductive polymer include chlorine-, bromine-, or iodine-doped polyacetylene, polyacene, polypyrrole, and polythiophene, and derivatives thereof.

Any appropriate supporting substrate may be employed as the above-mentioned supporting substrate. Examples of the supporting substrate include a glass substrate and a plastic substrate.

The quantum dot-sensitized solar cell of the present invention may be in a form of a wet solar cell, or may be in a form of a dry solar cell. An electrolyte may be interposed between the quantum dot-sensitized solar cell electrode of the present invention and the counter electrode. A liquid electrolyte or a solid electrolyte may be used as the electrolyte. Any appropriate liquid electrolyte may be employed as the liquid electrolyte. Any appropriate solid electrolyte may be employed as the solid electrolyte.

The quantum dot-sensitized solar cell of the present invention uses the quantum dot-sensitized solar cell electrode of the present invention, and hence has extremely high IPCE. To be specific, the quantum dot-sensitized solar cell of the present invention has IPCE of preferably 70% or more, more preferably 72% or more, even more preferably 75% or more, particularly preferably 77% or more, most preferably 80% or more. A conventional quantum dot-sensitized solar cell has IPCE of generally 40 to 50% even in one showing relatively high performance, around 60% even in one showing particularly high performance (see, for example, Patent Documents 2 and 3). It is therefore understood that the quantum dot-sensitized solar cell of the present invention have achieved extremely high IPCE.

The quantum dot-sensitized solar cell of the present invention uses the quantum dot-sensitized solar cell electrode of the present invention, and hence can exert such a high level of power conversion efficiency that may indicate its high practical applicability in the future. To be specific, the quantum dot-sensitized solar cell of the present invention has power conversion efficiency of preferably 1.25% or more, more preferably 1.5% or more, even more preferably 1.75% or more, particularly preferably 2% or more.

### EXAMPLES

Hereinafter, the present invention is described in more detail by way of examples. However, the present invention is by no means limited to these examples.

### Production Example 1

### Manufacture of Porous Titanium Oxide-FTO Conductive Film Electrode Having Thickness of 5 μm

Titanium oxide particles (PST-18NR manufactured by JGC Catalysts and Chemicals Ltd., particle size=20 nm) were applied onto a glass substrate (surface resistance=12 Ω/□) provided with a fluorine-doped tin oxide (FTO) conductive film by a doctor blade method, and the resultant substrate was baked at 500° C. for 1 hour to manufacture a porous titanium oxide-FTO conductive film electrode (mp-TiO₂—S) having a thickness of 5 μm.

### Production Example 2

### Manufacture of Porous Titanium Oxide-FTO Conductive Film Electrode Having Thickness of 0.5 μm

Titanium oxide particles (PST-400C manufactured by JGC Catalysts and Chemicals Ltd., particle size=400 nm) were applied onto a glass substrate (surface resistance=12 Ω/□) provided with a fluorine-doped tin oxide (FTO) conductive film by a doctor blade method, and the resultant substrate was baked at 500° C. for 1 hour to manufacture a porous titanium oxide-FTO conductive film electrode (mp-TiO₂-L) having a thickness of 0.5 μm.

### Example 1

### Manufacture of [CdS(PD)/mp-TiO₂—S] Quantum Dot-Sensitized Solar Cell Electrodes by Photodeposition (PD) Technique

Porous titanium oxide-FTO conductive film electrodes (mp-TiO₂—S) were immersed in 250 ml of ethanol solutions containing S₈ (1.72×10⁻⁴ mol/L) and Cd(_{ClO}₄)₂ (2.76×10⁻⁴ mol/L, 5.52×10⁻⁴ mol/L, 1.38×10⁻³mol/L, 3.45×10⁻³mol/L, 6.90×10⁻³mol/L, and 1.38×10⁻² mol/L). After an argon gas had been blown into the solutions under a light-shielding condition for 30 minutes, UV light irradiation was performed using a high-pressure mercury lamp at 25° C. The high-pressure mercury lamp used had a light intensity of 3.7 mW/cm (wavelength=320 to 400 nm). After the UV light irradiation, the resultant electrodes were washed three times with ethanol and dried to afford [CdS(PD)/mp-TiO₂—S] quantum dot-sensitized solar cell electrodes (S-1) to (S-6).

In the quantum dot-sensitized solar cell electrode (S-1) (initial concentration of Cd(ClO₄)₂ in solution=2.76×10⁻⁴ mol/L) after the UV light irradiation for 3 hours, the loading amount of the CdS quantum dots was 71.7 μg/cm² and the particle size of each of the CdS quantum dots was 5.3 nm.

In the quantum dot-sensitized solar cell electrode (S-2) (initial concentration of Cd(ClO₄)₂ in solution=5.52×10⁻⁴ mol/L) after the UV light irradiation for 3 hours, the loading amount of the CdS quantum dots was 116.8 μg/cm² and the particle size of each of the CdS quantum dots was 5.9 nm.

In the quantum dot-sensitized solar cell electrode (S-3) (initial concentration of Cd(ClO₄)₂ in solution=1.38×10⁻³ mol/L) after the UV light irradiation for 3 hours, the loading amount of the CdS quantum dots was 114.0 μg/cm² and the particle size of each of the CdS quantum dots was 6.2 nm.

In the quantum dot-sensitized solar cell electrode (S-4) (initial concentration of Cd(ClO₄)₂ in solution=3.45×10⁻³ mol/L) after the UV light irradiation for 3 hours, the loading amount of the CdS quantum dots was 143.5 μg/cm² and the particle size of each of the CdS quantum dots was 6.8 nm.

In the quantum dot-sensitized solar cell electrode (S-5) (initial concentration of Cd(ClO₄)₂ in solution=6.90×10⁻³ mol/L) after the UV light irradiation for 3 hours, the loading amount of the CdS quantum dots was 105.4 μg/cm² and the particle size of each of the CdS quantum dots was 5.7 nm.

In the quantum dot-sensitized solar cell electrode (S-6) (initial concentration of Cd(ClO₄)₂ in solution=1.38×10⁻² mol/L) after the UV light irradiation for 3 hours, the loading amount of the CdS quantum dots was 134.5 μg/cm² and the particle size of each of the CdS quantum dots was 5.9 nm.

### Example 2

### Manufacture of [CdS(PD)/mp-TiO₂-L] Quantum Dot-Sensitized Solar Cell Electrodes by Photodeposition (PD) Technique

Porous titanium oxide-FTO conductive film electrodes (mp-TiO₂-L) were immersed in 250 ml of ethanol solutions containing S₈ (1.72×10⁻⁴ mol/L) and Cd(ClO₄)₂ (2.76×10⁻⁴ mol/L, 5.52×10⁻⁴ mol/L, 1.38×10⁻³mol/L,3.45×10⁻³mol/L, 6.90×10⁻³mol/L,and1.38×10⁻² mol/L). After an argon gas had been blown into the solutions under a light-shielding condition for 30 minutes, UV light irradiation was performed using a high-pressure mercury lamp at 25° C. The high-pressure mercury lamp used had a light intensity of 3.7 mW/cm (wavelength=320 to 400 nm). After the UV light irradiation, the resultant electrodes were washed three times with ethanol and dried to afford [CdS(PD)/mp-TiO₂-L] quantum dot-sensitized solar cell electrodes (L-1) to (L-6).

In the quantum dot-sensitized solar cell electrode (L-1) (initial concentration of Cd(ClO₄)₂ in solution=2.76×10⁻⁴ mol/L) after the UV light irradiation for 3 hours, the loading amount of the CdS quantum dots was 30.6 μg/cm² and the particle size of each of the CdS quantum dots was 6.5 nm.

In the quantum dot-sensitized solar cell electrode (L-2) (initial concentration of Cd(ClO₄)₂ in solution=5.52×10⁻⁴ mol/L) after the UV light irradiation for 3 hours, the loading amount of the CdS quantum dots was 31.6 μg/cm² and the particle size of each of the CdS quantum dots was 6.3 nm.

In the quantum dot-sensitized solar cell electrode (L-3) (initial concentration of Cd(ClO₄)₂ in solution=1.38×10⁻³ mol/L) after the UV light irradiation for 3 hours, the loading amount of the CdS quantum dots was 27.1 μg/cm² and the particle size of each of the CdS quantum dots was 6.5 nm.

In the quantum dot-sensitized solar cell electrode (L-4) (initial concentration of Cd(ClO₄)₂ in solution=3.45×10⁻³ mol/L) after the UV light irradiation for 3 hours, the loading amount of the CdS quantum dots was 26.6 μg/cm² and the particle size of each of the CdS quantum dots was 7.6 nm.

In the quantum dot-sensitized solar cell electrode (L-5) (initial concentration of Cd(ClO₄)₂ in solution=6.90×10⁻³ mol/L) after the UV light irradiation for 3 hours, the loading amount of the CdS quantum dots was 31.4 μg/cm² and the particle size of each of the CdS quantum dots was 7.6 nm.

In the quantum dot-sensitized solar cell electrode (L-6) (initial concentration of Cd(ClO₄)₂ in solution=1.38×10⁻² mol/L) after the UV light irradiation for 3 hours, the loading amount of the CdS quantum dots was 31.8 μg/cm² and the particle size of each of the CdS quantum dots was 6.8 nm.

### Example 3

### Manufacture of [CdSe(PD)/mp-TiO₂—S] Quantum Dot-Sensitized Solar Cell Electrode by Photodeposition (PD) Technique

250 mL of an ethanol solution obtained by dissolving 1.4 g (3.0×10⁻³ mol) of Cd(ClO₄)₂.6H₂O and 0.44 g (3.4×10⁻³ mol) of H₂SeO₃ were charged into an inner vessel of a double-jacketed reactor made of Pyrex (registered trademark), followed by degassing with Ar (120 cm³min⁻¹) for 20 minutes. A porous titanium oxide-FTO conductive film electrode (mp-TiO₂—S) was placed therein, followed by further degassing with Ar (120 cm min⁻¹) for 10 minutes. UV light (λₑₓ>320 nm) irradiation was performed using a high-pressure mercury lamp under degassing with Ar. The high-pressure mercury lamp used had a light intensity of 3.6 mW/cm (wavelength=310 to 410 nm). During this time, in order to keep the temperature in the system constant, water was circulated through an outer vessel of the double-jacketed reactor (25° C±1° C.). Thus, a [CdSe(PD)/mp-TiO₂—S] quantum dot-sensitized solar cell electrode (S-7) was obtained.

### Example 4

### Manufacture of [PbS(PD)/mp-TiO₂—S] Quantum Dot-Sensitized Solar Cell Electrode by Photodeposition (PD) Technique

After an argon gas had been blown into a suspension (250 mL) of TiO₂ particles (1 g) in ethanol, containing S₈ (1.72×10⁻⁴ mol/L), Pb(ClO₄)₂ (1.2×10⁻² mol/L), and mercaptoacetic acid (4×10⁻⁴ mol/L) under a light-shielding condition for 30 minutes, UV light irradiation was performed using a high-pressure mercury lamp at 25° C. The high-pressure mercury lamp used had a light intensity of 3.6 mW/cm (wavelength=320 to 400 nm). After the UV light irradiation, particles were collected by centrifugation, followed by washing with ethanol and drying under reduced pressure. Thus, a [PbS(PD)/mp-TiO₂—S] quantum dot-sensitized solar cell electrode (S-8) was obtained.

### Comparative Example 1

### Manufacture of [CdS(SAM)/mp-TiO₂—S] Quantum Dot-Sensitized Solar Cell Electrode by Self-Assembled Monolayer (SAM) Method

To 150 ml of an aqueous solution of Na₂S (1.00×10⁻⁵ mol/L) and mercaptoacetic acid (4.00×10⁻⁵mol/L), 150 ml of an aqueous solution of Cd(_{ClO}₄)₂ (3.46×10⁻³ mol/L) were added dropwise slowly, and the mixture was stirred for 20 minutes. A porous titanium oxide-FTO conductive film electrode (mp-TiO₂—S) was immersed in the resultant solution. After the adsorption of CdS quantum dots, the resultant electrode was washed three times with pure water and dried to afford a [CdS (SAM)/mp-TiO₂—S] quantum dot-sensitized solar cell electrode (Comparative S-1).

### Comparative Example 2

### Manufacture of [CdS (SAM)/mp-TiO₂-L] Quantum Dot-Sensitized Solar Cell Electrode by Self-Assembled Monolayer (SAM) Method

To 150 ml of an aqueous solution of Na₂S (1.00×10⁻⁵ mol/L) and mercaptoacetic acid (4.00×10⁻⁵ mol/L), 150 ml of an aqueous solution of Cd (ClO₄)₂ (3.46×10⁻³ mol/L) were added dropwise slowly, and the mixture was stirred for 20 minutes. A porous titanium oxide-FTO conductive film electrode (mp-TiO₂-L) was immersed in the resultant solution. After the adsorption of CdS quantum dots, the resultant electrode was washed three times with pure water and dried to afford a [CdS (SAM)/mp-TiO₂-L] quantum dot-sensitized solar cell electrode (Comparative L-1).

### Comparative Example 3

### Manufacture of [CdS (SAM)/mp-TiO₂—S] Quantum Dot-Sensitized Solar Cell Electrode by Self-Assembled Monolayer (SAM) Method

To 150 ml of an aqueous solution of Na₂S (1.00×10⁻⁵ mol/L) and mercaptoacetic acid (1.00×10⁻⁵ mol/L), 150 ml of an aqueous solution of Cd (ClO₄)₂ (3.46×10⁻³ mol/L) were added dropwise slowly, and the mixture was stirred for 20 minutes. A porous titanium oxide-FTO conductive film electrode (mp-TiO₂—S) was immersed in the resultant solution. After the adsorption of CdS quantum dots, the resultant electrode was washed three times with pure water and dried to afford a [CdS (SAM)/mp-TiO₂—S] quantum dot-sensitized solar cell electrode (Comparative S-2).

### Comparative Example 4

### Manufacture of [CdS (SILAR, n=7)/mp-TiO₂—S] Quantum Dot-Sensitized Solar Cell Electrode by Successive Ionic Layer Adsorption and Reaction (SILAR) Method

A porous titanium oxide-FTO conductive film electrode (mp-TiO₂—S) was immersed in a solution of Cd(ClO₄)₂ (5.0×10⁻² mol/L) in ethanol (20 mL) at room temperature for 1 minute. After that, the electrode was washed with pure ethanol and dried in air. Subsequently, the resultant electrode was immersed in a solution of Na₂S (5.0×10⁻² mol/L) in ethanol (20 mL) at room temperature for 1 minute. After that, the electrode was washed with pure ethanol and dried in air. Such immersion cycle was repeated seven times (n=7) to afford a [CdS(SILAR)/mp-TiO₂—S] quantum dot-sensitized solar cell electrode (Comparative S-3).

### Comparative Example 5

### Manufacture of [CdS (SILAR, n=3)/mp-TiO₂—S] Quantum Dot-Sensitized Solar Cell Electrode by Successive Ionic Layer Adsorption and Reaction (SILAR) Method

A porous titanium oxide-FTO conductive film electrode (mp-TiO₂—S) was immersed in a solution of Cd(ClO₄)₂ (5.0×10⁻² mol/L) in ethanol (20 mL) at room temperature for 1 minute. After that, the electrode was washed with pure ethanol and dried in air. Subsequently, the resultant electrode was immersed in a solution of Na₂S (5.0×10⁻² mol/L) in ethanol (20 mL) at room temperature for 1 minute. After that, the electrode was washed with pure ethanol and dried in air. Such immersion cycle was repeated three times (n=3) to afford a [CdS(SILAR)/mp-TiO₂—S] quantum dot-sensitized solar cell electrode (Comparative S-4).

### Example 5

### CdS (PD)/mp-TiO₂—S] Quantum Dot-Sensitized Solar Cell

A gold thin film having a thickness of 100 nm was formed by vacuum deposition on a non-alkaline glass plate (NA35 manufactured by Nippon Sheet Glass Co., Ltd.) provided with a chromium undercoat layer having a thickness of 20 nm. The [CdS (PD)/mp-TiO₂—S] quantum dot-sensitized solar cell electrodes (S-1) to (S-6) obtained in Example 1 were each used as a counter electrode. The cell gap was adjusted to 60 μm and the cell active area was set to 1.76 cm². An electrolyte solution was injected into the above-mentioned two electrodes to produce [CdS(PD)/mp-TiO₂—S] quantum dot-sensitized solar cells (SC-S-1) to (SC-S-6). The electrolyte solution used was one obtained by blowing argon into an aqueous solution of Na₂S (0.1 mol/L), Na₂SO₃ (5.4×10⁻³ mol/L), and NaClO₄ (0.1 mol/L) to remove oxygen in the aqueous solution.

### Example 6

### CdS (PD)/mp-TiO₂-L] Quantum Dot-Sensitized Solar Cell

A gold thin film having a thickness of 100 nm was formed by vacuum deposition on a non-alkaline glass plate (NA35 manufactured by Nippon Sheet Glass Co., Ltd.) provided with a chromium undercoat layer having a thickness of 20 nm. The [CdS (PD)/mp-TiO₂-L] quantum dot-sensitized solar cell electrodes (L-1) to (L-6) obtained in Example 2 were each used as a counter electrode. The cell gap was adjusted to 60 μm and the cell active area was set to 1.76 cm². An electrolyte solution was injected into the above-mentioned two electrodes to produce [CdS(PD)/mp-TiO₂-L] quantum dot-sensitized solar cells (SC-L-1) to (SC-L-6). The electrolyte solution used was one obtained by blowing argon into an aqueous solution of Na₂S (0.1 mol/L), Na₂SO₃ (5.4×10⁻³ mol/L), and NaClO₄ (0.1 mol/L) to remove oxygen in the aqueous solution.

### Example 7

### CdSe(PD)/mp-TiO₂—S] Quantum Dot-Sensitized Solar Cell

A gold thin film having a thickness of 100 nm was formed by vacuum deposition on a non-alkaline glass plate (NA35 manufactured by Nippon Sheet Glass Co., Ltd.) provided with a chromium undercoat layer having a thickness of 20 nm. The [CdSe(PD)/mp-TiO₂—S] quantum dot-sensitized solar cell electrode (S-7) obtained in Example 3 was used as a counter electrode. The cell gap was adjusted to 60 pm and the cell active area was set to 1.76 cm². An electrolyte solution was injected into the above-mentioned two electrodes to produce a [CdSe(PD)/mp-TiO₂—S] quantum dot-sensitized solar cell (SC-S-7). The electrolyte solution used was one obtained by blowing argon into an aqueous solution of Na₂S (0.1 mol/L), Na₂SO₃ (5.4×10⁻³ mol/L), and NaClO₄ (0.1 mol/L) to remove oxygen in the aqueous solution.

### Example 8

### PbS (PD)/mp-TiO₂—S] Quantum Dot-Sensitized Solar Cell

A gold thin film having a thickness of 100 nm was formed by vacuum deposition on a non-alkaline glass plate (NA35 manufactured by Nippon Sheet Glass Co., Ltd.) provided with a chromium undercoat layer having a thickness of 20 nm. The [PbS (PD)/mp-TiO₂—S] quantum dot-sensitized solar cell electrode (S-8) obtained in Example 4 was used as a counter electrode. The cell gap was adjusted to 60 μm and the cell active area was set to 1.76 cm². An electrolyte solution was injected into the above-mentioned two electrodes to produce a [PbS(PD)/mp-TiO₂—S] quantum dot-sensitized solar cell (SC-S-8). The electrolyte solution used was one obtained by blowing argon into an aqueous solution of Na₂S (0.1 mol/L), Na₂SO₃ (5.4×10⁻³ mol/L), and NaClO₄ (0.1 mol/L) to remove oxygen in the aqueous solution.

### Comparative Example 6

### CdS(SAM)/mp-TiO₂—S] Quantum Dot-Sensitized Solar Cell

A gold thin film having a thickness of 100 nm was formed by vacuum deposition on a non-alkaline glass plate (NA35 manufactured by Nippon Sheet Glass Co., Ltd.) provided with a chromium undercoat layer having a thickness of 20 nm. The [CdS(SAM)/mp-TiO₂—S] quantum dot-sensitized solar cell electrode (Comparative S-1) obtained in Comparative Example 1 was used as a counter electrode. The cell gap was adjusted to 60 μm and the cell active area was set to 1.76 cm². An electrolyte solution was injected into the above-mentioned two electrodes to produce a [CdS(SAM)/mp-TiO₂—S] quantum dot-sensitized solar cell (Comparative SC-S-1). The electrolyte solution used was one obtained by blowing argon into an aqueous solution of Na₂S (0.1 mol/L), Na₂SO₃ (5.4×10⁻³ mol/L), and NaClO₄ (0.1 mol/L) to remove oxygen in the aqueous solution.

### Comparative Example 7

### CdS(SAM)/mp-TiO₂-L] Quantum Dot-Sensitized Solar Cell

A gold thin film having a thickness of 100 nm was formed by vacuum deposition on a non-alkaline glass plate (NA35 manufactured by Nippon Sheet Glass Co., Ltd.) provided with a chromium undercoat layer having a thickness of 20 nm. The [CdS(SAM)/mp-TiO₂-L] quantum dot-sensitized solar cell electrode (Comparative L-1) obtained in Comparative Example 2 was used as a counter electrode. The cell gap was adjusted to 60 μm and the cell active area was set to 1.76 cm². An electrolyte solution was injected into the above-mentioned two electrodes to produce a [CdS(SAM)/mp-TiO₂-L] quantum dot-sensitized solar cell (Comparative SC-L-1). The electrolyte solution used was one obtained by blowing argon into an aqueous solution of Na₂S (0.1 mol/L), Na₂SO₃ (5.4×10⁻³ mol/L), and NaClO₄ (0.1 mol/L) to remove oxygen in the aqueous solution.

### Comparative Example 8

### CdS(SAM)/mp-TiO₂—S] Quantum Dot-Sensitized Solar Cell

A gold thin film having a thickness of 100 nm was formed by vacuum deposition on a non-alkaline glass plate (NA35 manufactured by Nippon Sheet Glass Co., Ltd.) provided with a chromium undercoat layer having a thickness of 20 nm. The [CdS(SAM)/mp-TiO₂—S] quantum dot-sensitized solar cell electrode (Comparative S-2) obtained in Comparative Example 3 was used as a counter electrode. The cell gap was adjusted to 60 μm and the cell active area was set to 1.76 cm². An electrolyte solution was injected into the above-mentioned two electrodes to produce a [CdS(SAM)/mp-TiO₂—S] quantum dot-sensitized solar cell (Comparative SC-S-2). The electrolyte solution used was one obtained by blowing argon into an aqueous solution of Na₂S (0.1 mol/L), Na₂SO₂ (5.4×10⁻³ mol/L), and NaClO₄ (0.1 mol/L) to remove oxygen in the aqueous solution.

### Comparative Example 9

### CdS(SILAR, n=7)/mp-TiO₂—S] Quantum Dot-Sensitized Solar Cell

A gold thin film having a thickness of 100 nm was formed by vacuum deposition on a non-alkaline glass plate (NA35 manufactured by Nippon Sheet Glass Co., Ltd.) provided with a chromium undercoat layer having a thickness of 20 nm. The [CdS (SILAR, n=7)/mp-TiO₂—S] quantum dot-sensitized solar cell electrode (Comparative S-3) obtained in Comparative Example 4 was used as a counter electrode. The cell gap was adjusted to 60 μm and the cell active area was set to 1.76 cm². An electrolyte solution was injected into the above-mentioned two electrodes to produce a [CdS(SILAR, n=7)/mp-TiO₂—S] quantum dot-sensitized solar cell (Comparative SC-S-3). The electrolyte solution used was one obtained by blowing argon into an aqueous solution of Na₂S (0.1 mol/L), Na₂SO₃ (5.4×10⁻³ mol/L), and NaClO₄ (0.1 mol/L) to remove oxygen in the aqueous solution.

### Comparative Example 10

### CdS(SILAR, n=3)/mp-TiO₂—S] Quantum Dot-Sensitized Solar Cell

A gold thin film having a thickness of 100 nm was formed by vacuum deposition on a non-alkaline glass plate (NA35 manufactured by Nippon Sheet Glass Co., Ltd.) provided with a chromium undercoat layer having a thickness of 20 nm. The [CdS (SILAR, n=3)/mp-TiO₂—S] quantum dot-sensitized solar cell electrode (Comparative S-4) obtained in Comparative Example 5 was used as a counter electrode. The cell gap was adjusted to 60 μm and the cell active area was set to 1.76 cm². An electrolyte solution was injected into the above-mentioned two electrodes to produce a [CdS(SILAR, n=3)/mp-TiO₂—S] quantum dot-sensitized solar cell (Comparative SC-S-4). The electrolyte solution used was one obtained by blowing argon into an aqueous solution of Na₂S (0.1 mol/L), Na₂SO₃ (5.4×10⁻³ mol/L), and NaClO₄ (0.1 mol/L) to remove oxygen in the aqueous solution.

### [Evaluation 1]: Relationship Between UV Light Irradiation Time or Adsorption Time and Quantum Dot Formation Amount

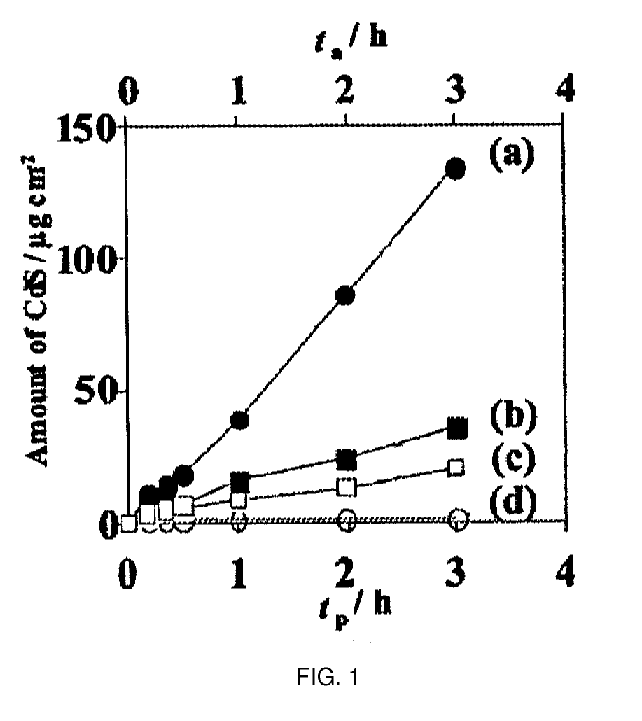

With regard to the quantum dot-sensitized solar cell electrode (S-3) obtained in Example 1 (initial concentration of Cd(ClO₄)₂ in solution=1.38×10⁻³ mol/L), the quantum dot-sensitized solar cell electrode (L-3) obtained in Example 2 (initial concentration of Cd(ClO₄)₂ in solution=1.38×10⁻³mol/L), the quantum dot-sensitized solar cell electrode (Comparative S-1) obtained in Comparative Example 1, and the quantum dot-sensitized solar cell electrode (Comparative L-1) obtained in Comparative Example 2, a relationship between UV light irradiation time (tₚ) and a quantum dot formation amount was plotted for each of the electrodes (S-3) and (L-3), and a relationship between adsorption time (tₐ) and a quantum dot formation amount was plotted for each of the electrodes (Comparative S-1) and (Comparative L-1). FIGS. 1 illustrate the results. In FIGS. 1, FIG. 1(a) is a graph of the quantum dot-sensitized solar cell electrode (S-3), FIG. 1(b) is a graph of the quantum dot-sensitized solar cell electrode (L-3), FIG. 1(c) is a graph of the quantum dot-sensitized solar cell electrode (Comparative L-1), and FIG. 1(d) is a graph of the quantum dot-sensitized solar cell electrode (Comparative S-1).

As illustrated in FIGS. 1, the quantum dot formation amount almost linearly increases with increasing UV light irradiation time (tₚ) during the manufacture of the quantum dot-sensitized solar cell electrode of the present invention. The quantum dot formation amount after irradiation for 3 hours for the quantum dot-sensitized solar cell electrode (S-3) was 134.5 μg/cm². The quantum dot formation amount after irradiation for 3 hours for the quantum dot-sensitized solar cell electrode (L-3) was 34.7 μg/cm². In contrast, when a quantum dot-sensitized solar cell electrode is manufactured by a conventional manufacturing method, the quantum dot formation amount after adsorption for 3 hours for the quantum dot-sensitized solar cell electrode (Comparative L-1) was 19.2 μg/cm² and the quantum dot formation amount after adsorption for 3 hours for the quantum dot-sensitized solar cell electrode (Comparative S-1) was 0.9 μg/cm² . Those results reveal that, according to the manufacturing method for a quantum dot-sensitized solar cell electrode of the present invention, quantum dots are deposited and loaded on an electrode in a very efficient manner as compared to the conventional manufacturing method.

### [Evaluation 2]: Influence of Initial Concentration of Cd(ClO₄)₂ in Solution in Manufacturing Method of Present Invention

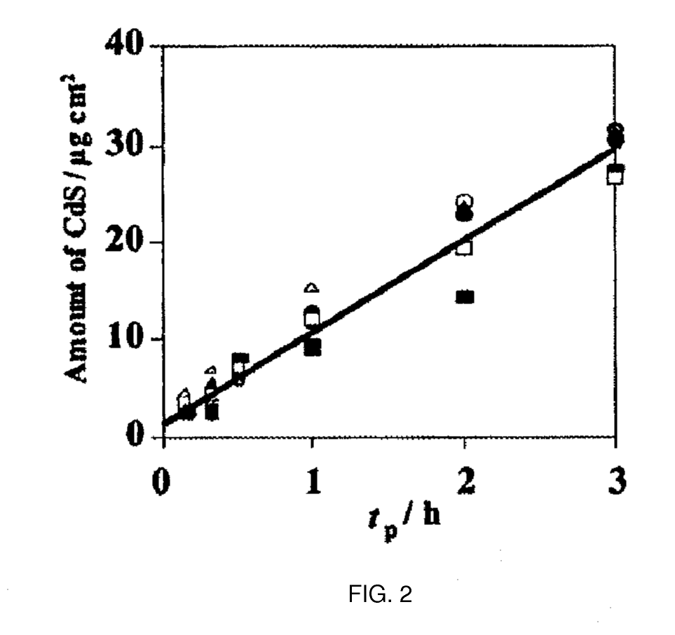

A relationship between UV light irradiation time (tₚ) and a quantum dot formation amount was plotted for each of the quantum dot-sensitized solar cell electrodes (L-1) to (L-6) obtained in Example 2. FIGS. 2 illustrates the results.

The initial concentration of Cd (ClO₄)₂ in the solution during the manufacture of the quantum dot-sensitized solar cell electrode (L-1) was 2.76×10⁻⁴ mol/L, the initial concentration of Cd (ClO₄)₂ in the solution during the manufacture of the quantum dot-sensitized solar cell electrode (L-2) was 5.52×10⁻⁴ mol/L, the initial concentration of Cd (ClO₄)₂ in the solution during the manufacture of the quantumdot-sensitized solar cell electrode (L-3) was 1.38×10⁻³ mol/L, the initial concentration of Cd (ClO₄)₂ in the solution during the manufacture of the quantum dot-sensitized solar cell electrode (L-4) was 3.45×10⁻³ mol/L, the initial concentration of Cd (ClO₄)₂ in the solution during the manufacture of the quantum dot-sensitized solar cell electrode (L-5) was 6.90×10⁻³ mol/L, and the initial concentration of Cd (ClO₄)₂ in the solution during the manufacture of the quantumdot-sensitized solar cell electrode (L-6) was 1.38×10⁻² mol/L.

In FIGS. 2, the data on the quantum dot-sensitized solar cell electrode (L-1) is represented by open triangles Δ, the data on the quantum dot-sensitized solar cell electrode (L-2) is represented by solid triangles ▴, the data on the quantum dot-sensitized solar cell electrode (L-3) is represented by open squares □, the data on the quantum dot-sensitized solar cell electrode (L-4) is representedby solid squares ▪, the data on the quantum dot-sensitized solar cell electrode (L-5) is represented by open circles ∘, and the data on the quantum dot-sensitized solar cell electrode (L-6) is represented by solid circles .

As illustrated in FIGS. 2, a difference in initial concentration of Cd(ClO₄)₂ in a solution has very little influence on the quantum dot formation amount during the manufacture of the quantum dot-sensitized solar cell electrode of the present invention. In other words, it is understood that, according to the manufacturing method for a quantum dot-sensitized solar cell electrode of the present invention, quantum dot-sensitized solar cell electrodes having the same quality can be obtained with good reproducibility irrespective of the composition of a solution in which the electrode is immersed.

### [Evaluation 3]: Evaluation of Quantum Dot-Sensitized Solar Cell for IPCE

The resultant quantum dot-sensitized solar cell was measured for its incident photon to current conversion efficiency (IPCE). The IPCE was measured under a short-circuit condition using a potentiostat/galvanostat (HZ-5000 manufactured by Hokuto Denko Corporation), and irradiation was performed using a Xe lamp provided with a monochrometer (fwhm, 10 nm) (HM-5 manufactured by JASCO Corporation).

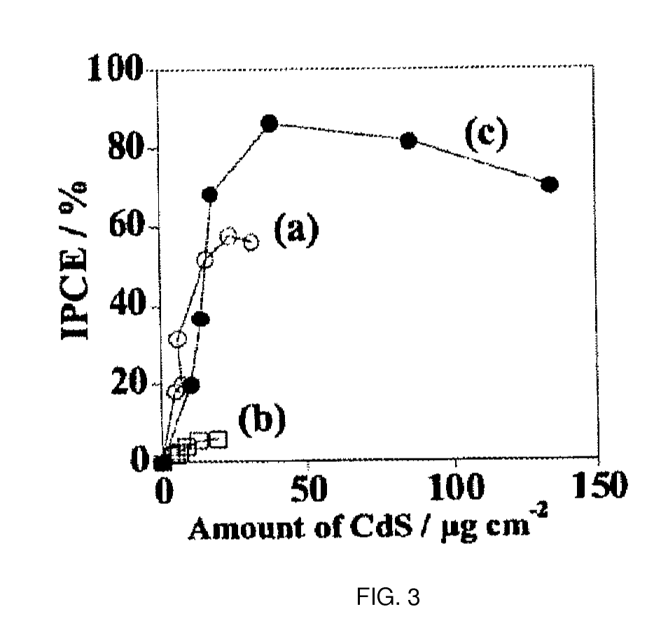

FIG. 3 are graphs plotting relationships between an IPCE amount and a quantum dot formation amount for the quantum dot-sensitized solar cell (SC-S-3) obtained in Example 5, the quantum dot-sensitized solar cell (SC-L-3) obtained in Example 6, and the quantum dot-sensitized solar cell (Comparative SC-L-1) obtained in Comparative Example 7. In FIGS. 3, FIG. 3(a) is a graph of the [CdS(PD)/mp-TiO₂-L] quantumdot-sensitized solar cell (SC-L-3), FIG. 3(b) is a graph of the [CdS (SAM)/mp-TiO₂-L] quantum dot-sensitized solar cell (Comparative SC-L-1), and FIG. 3(c) is a graph of the [CdS(PD)/mp-TiO₂—S] quantum dot-sensitized solar cell (SC-S-3).

As illustrated in FIGS. 3, the quantum dot-sensitized solar cell of the present invention exhibited extremely high IPCE and exhibited IPCE of up to near 90%.

### [Evaluation 4]: Measurement of Quantum Dot-Sensitized Solar Cell for Power Conversion Efficiency (η)

The power conversion efficiency (η) of the quantum dot-sensitized solar cell was measured for each of the [CdS(PD)/mp-TiO₂—S] quantum dot-sensitized solar cell (SC-S-3) obtained in Example 5, the [CdSe(PD)/mp-TiO₂—S] quantum dot-sensitized solar cell (SC-S-7) obtained in Example 7, the [PbS(PD)/mp-TiO₂—S] quantum dot-sensitized solar cell (SC-S-8) obtained in Example 8, the [CdS(SAM)/mp-TiO₂—S] quantum dot-sensitized solar cell (Comparative SC-S-2) obtained in Comparative Example 8, the [CdS(SILAR, n=7)/mp-TiO₂—S] quantum dot-sensitized solar cell (Comparative SC-S-3) obtained in Comparative Example 9, and the [CdS (SILAR, n=3)/mp-TiO₂—S] quantum dot-sensitized solar cell (Comparative SC-S-4) obtained in Comparative Example 10.

A measurement method for the power conversion efficiency (η) of the quantum dot-sensitized solar cell involved measuring a current-potential curve using a potentio/galvanostat (HZ-5000 manufactured by Hokuto Denko Corporation) under simulated solar light irradiation (PEC-L10 manufactured by Peccell Technologies, Inc., AM1.5, light intensity Iₛ=100 mWcm⁻²). The power conversion efficiency (η) was calculated from the obtained short-circuit current (J_{sc}[mA/cm²]), open-circuit voltage (V_{oc}[V]),andfill factor (ff) values based on the following equation:

η(%)=(J_{sc}V_{oc}ff/Iₛ)×100

Table 1 shows, as representative results, the results of the [CdS(PD)/mp-TiO₂—S] quantum dot-sensitized solar cell (SC-S-3) obtained in Example 5, the [CdS(SAM)/mp-TiO₂—S] quantum dot-sensitized solar cell (Comparative SC-S-2) obtained in Comparative Example 8, and the [CdS (SILAR, n=7)/mp-TiO₂—S] quantum dot-sensitized solar cell (Comparative SC-S-3) obtained in Comparative Example 9.

It should be noted that, although not shown in Table 1, the following was confirmed. That is, the [CdSe(PD)/mp-TiO₂—S] quantum dot-sensitized solar cell (SC-S-7) obtained in Example 7 and the [PbS(PD)/mp-TiO₂—S] quantum dot-sensitized solar cell (SC-S-8) obtained in Example 8 can also exert such a high level of power conversion efficiency that may indicate their high practical applicability in the future, and sufficiently function as solar cells in the same manner as the [CdS(PD)/mp-TiO₂—S] quantum dot-sensitized solar cell (SC-S-3) obtained in Example 5.

In contrast, although not shown in Table 1, the [CdS(SILAR, n=3)/mp-TiO₂—S] quantum dot-sensitized solar cell (Comparative SC-S-4) obtained in Comparative Example 10 gave a lower level of power conversion efficiency than that of the [CdS(SILAR, n=7)/mp-TiO₂—S] quantum dot-sensitized solar cell (Comparative SC-S-3) obtained in Comparative Example 9.

TABLE 1

| | Power conversion |
|---|---|
| | efficiency (%) |
| Quantum dot-sensitized solar cell | (η) |
| [CdS(PD)/mp-TiO₂—S] | 2.51 |
| quantum dot-sensitized solar cell | |
| (SC-S-3) | |
| [CdS(SAM)/mp-TiO₂—S] | 0.14 |
| quantum dot-sensitized solar cell | |
| (Comparative SC-S-2) | |
| [CdS(SILAR, n = 7)/mp-TiO₂—S] | 1.21 |
| quantum dot-sensitized solar cell | |
| (Comparative SC-S-3) | |

### [Evaluation 5] : Analysis Based on X-ray Photoelectron Spectroscopy (XPS)

X-ray photoelectron spectroscopy (XPS)-based measurement was performed from the surface on the side opposite to a transparent electrode for each of the [CdS(PD)/mp-TiO₂—S] quantum dot-sensitized solar cell electrode (S-3) obtained in Example 1, the [CdS(SILAR, n=7)/mp-TiO₂—S] quantum dot-sensitized solar cell electrode (Comparative S-3) obtained in Comparative Example 4, and the [CdS(SILAR, n=3)/mp-TiO₂—S] quantum dot-sensitized solar cell electrode (Comparative S-4) obtained in Comparative Example 5.

<Measurement Conditions>

Apparatus: Quantera SXM (manufactured by ULVAC-PHI, Inc.)

Excitation X-ray: monochromatic Al K_{α1,2}-ray (1486.6 eV)

X-ray size: 200 μm

Photoelectron take-off angle: 45°

Abscissa correction: a C1s main peak was fitted to 284.6 eV.

<Measurement Results>

The ratios of the number of atoms of Na, S, and Cd were compared based on their area ratios. S had a peak attributed to Na₂S on a higher energy side and a peak attributed to CdS on a lower energy side each observed by the SILAR method, and hence, the ratios of the number of atoms were individually determined for the respective peaks.

Table 2 and Table 3 show the results.

It should be noted that the evaluation results of the power conversion efficiency (I_{]}) of the solar cell in Table 3 were shown in accordance with the following evaluation criteria:

∘: η≧2

Δ: 1≦η2

×: η<1

TABLE 2

| | Ratio of number of atoms (with | | | |
|---|---|---|---|---|
| | respect to Cd defined as 1) | | | |
| | Na | S (low) | S (high) | Cd |
| CdS(PD)/mp-TiO₂—S] | — | — | 0.72 | 1 |
| quantum dot-sensitized solar | | | | |
| cell electrode | | | | |
| (S-3) | | | | |
| [CdS(SILAR, n = 7)/mp-TiO₂—S] | 1.06 | 0.53 | 0.53 | 1 |
| quantum dot-sensitized solar | | | | |
| cell electrode | | | | |
| (Comparative S-3) | | | | |
| [CdS(SILAR, n = 3)/mp-TiO₂—S] | 0.31 | 0.17 | 1.38 | 1 |
| quantum dot-sensitized solar | | | | |
| cell electrode | | | | |
| (Comparative S-4) | | | | |

TABLE 3

| | | Power conversion |
|---|---|---|
| | | efficiency (η) (%) |
| | a | of solar cell |
| CdS(PD)/mp-TiO₂—S] | 0.36 | ◯ |
| quantum dot-sensitized solar cell | | |
| electrode | | |
| (S-3) | | |
| [CdS(SILAR, n = 7)/mp-TiO₂—S] | 0.27 | Δ |
| quantum dot-sensitized solar cell | | |
| electrode | | |
| (Comparative S-3) | | |
| [CdS(SILAR, n = 3)/mp-TiO₂—S] | 0.69 | X |
| quantum dot-sensitized solar cell | | |
| electrode | | |
| (Comparative S-4) | | |

### INDUSTRIAL APPLICABILITY

The quantum dot-sensitized solar cell electrode in the present invention can be applied as a quantum dot-sensitized solar cell exhibiting extremely high IPCE efficiency and such a high level of power conversion efficiency that may indicate its high practical applicability in the future.

1. A manufacturing method for a quantum dot-sensitized solar cell electrode comprising quantum dots, which being semiconductor nanoparticles and having loaded on a porous n-type semiconductor electrode, the method comprising:
subjecting the porous n-type semiconductor electrode to photoirradiation while the electrode being immersed in a metal ion-containing solution.

2. A manufacturing method according to claim 1, wherein the metal ion-containing solution comprises a compound having a Group 16 element.

3. A manufacturing method according to claim 1, wherein the photoirradiation comprises UV light irradiation.

4. A quantum dot-sensitized solar cell electrode, which is obtained by the manufacturing method according to claim 1.

5. A quantum dot-sensitized solar cell comprising the quantum dot-sensitized solar cell electrode according to claim 4.

6. A quantum dot-sensitized solar cell according to claim 5, wherein the quantum dot-sensitized solar cell has IPCE efficiency of 70% or more.

7. A quantum dot-sensitized solar cell electrode comprising quantum dots being Group 16 element semiconductor nanoparticles and having loaded on a porous n-type semiconductor electrode, wherein
when the Group 16 element semiconductor nanoparticles are represented by MKₓ where M represents a metal element, K represents a Group 16 element, and x represents a number of atoms of K with respect to a number of atoms of M defined as 1, and
an expression a=x/y where y represents a valence of M is established,
an expression 0.3<a<0.6 is satisfied.

8. A quantum dot-sensitized solar cell comprising the quantum dot-sensitized solar cell electrode according to claim 7.

9. A quantum dot-sensitized solar cell according to claim 8, wherein the quantum dot-sensitized solar cell has IPCE efficiency of 70% or more.
